(19) United States
(12) Patent Application Publication
(10) Pub. No.: US 2025/0047273 A1
(43) Pub. Date: Feb. 6, 2025

(54) Power Clamp Circuitry

(71) Applicant: Arm Limited, Cambridge (GB)

(72) Inventors: Seshagiri Rao Bogi, Vizianagaram (IN); Gurupadayya Shidaganti, Hubli (IN); Vinay Chenani, Bangalore (IN); Fabrice Blanc, Vinay (FR)

(21) Appl. No.: 18/229,006

(22) Filed: Aug. 1, 2023

(51) Int. Cl. H03K 17/06; H03K 17/10; H03K 19/003

(52) U.S. Cl. CPC H03K 17/063; H02H 3/20; H03K 17/102; H03K 19/00315

(57) ABSTRACT

Various implementations described herein are directed to a device having an input-output stage with first transistors coupled between a voltage supply and ground. Also, the device may have a power clamping stage with resistor-capacitor circuitry coupled in parallel with second transistors between the voltage supply and ground. Also, during a power surging event, electro-static discharge is distributed across the first transistors and the second transistors by way of passing from the voltage supply to ground.

### BACKGROUND

This section is intended to provide information relevant to understanding the various technologies described herein. As the section's title implies, this is a discussion of related art that should in no way imply that it is prior art. Generally, related art may or may not be considered prior art. It should therefore be understood that any statement in this section should be read in this light, and not as any admission of prior art.

In some modern circuit architectures, sudden electro-static discharge (ESD) is typically harmful, and conventional ESD protection circuitry has high leakage issues that have increased voltage/current leakage due to the use of a large number of power clamps and output transistors. Also, some modern circuitry having a large number of input-output (IO) circuits suffer from high leakage issues with increased voltage/current leakage. Thus, there exists a need for more efficient ESD protection circuit schemes that reduce the high leakage issues by reducing voltage/current leakage of ESD protection circuitry.

### BRIEF DESCRIPTION OF THE DRAWINGS

Implementations of various techniques are described herein with reference to the accompanying drawings. It should be understood, however, that the accompanying drawings illustrate only various implementations described herein and are not meant to limit embodiments of various techniques described herein.

FIG. 1 illustrates a diagram of power clamp architecture in accordance with various implementations described herein.

FIG. 2 illustrates a diagram of input-output circuitry in accordance with various implementations described herein.

FIG. 3 illustrates a diagram of power clamp circuitry in accordance with various implementations described herein.

FIG. 4 illustrates a diagram of electro-static discharge (ESD) in power clamp architecture in accordance with various implementations described herein.

FIG. 5 illustrates a process diagram of a method for providing power clamp architecture in accordance with implementations described herein.

### DETAILED DESCRIPTION

Various implementations described herein are related to power clamp schemes and techniques for various circuit related applications in physical designs. Also, in some implementations, various power clamp schemes and techniques described herein provide for novel electro-static discharge (ESD) distribution that uses power clamp architecture to reduce leakage from ESD power clamps. In some implementations, the various power clamp schemes and techniques described herein may provide for low leakage ESD power clamp solutions based on contribution from input-output (IO) buffers. As such, the various power clamp schemes and techniques described herein may provide various techniques that reduce leakage from ESD power clamps in various circuit based applications.

Various implementations described herein provide for multiple stages including an input-output stage and a power clamping stage. The input-output stage may have first transistors coupled between a voltage supply and ground, and the power clamping stage may have resistor-capacitor circuitry coupled in parallel with second transistors between the voltage supply and ground. During a power surging event, electro-static discharge may be distributed across the first transistors and the second transistors by way of passing from the voltage supply to ground.

Various other implementations described herein may also provide for multiple stages including the input-output stage and the power clamping stage. The input-output stage may have assist circuitry and driver circuitry coupled between a voltage supply and ground, and the power clamping stage may have triggering circuitry and a big field-effect transistor (i.e., big FET) coupled between the voltage supply and ground. During a sudden power surging event, electro-static discharge may be distributed across the driver circuitry when triggered by the assist circuitry. Also, during the power surging event, the electro-static discharge may also be distributed across the big field-effect transistor (i.e., big FET) when triggered by the triggering circuitry.

Various other implementations described herein may also provide for a method that provides the input-output stage with the assist circuitry and the driver circuitry coupled between a voltage supply and ground. Also, the method may provide the power clamping stage with the triggering circuitry and the big field-effect transistor (i.e., big FET) coupled between the voltage supply and ground. Also, during a power surging event, the method may distribute electro-static discharge across the driver circuitry when triggered by the assist circuitry, and during the power surging event, the method may distribute electro-static discharge across the big field-effect transistor (i.e., big FET) when triggered by the triggering circuitry.

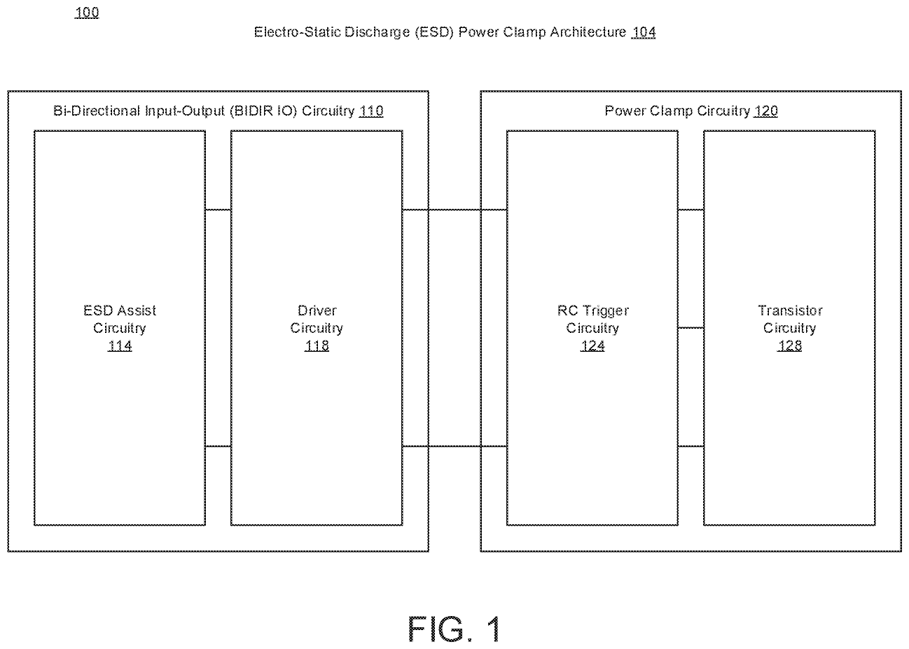

Various implementations of power clamp schemes and techniques for various circuit applications will be described herein in FIGS. 1-5.

FIG. 1 illustrates a schematic diagram 100 of power clamp architecture 104 in accordance with various implementations described herein.

In some implementations, power clamp architecture 104 provides for fabricating electro-static discharge (ESD) related circuitry with various integrated circuit components arranged and/or coupled together as an assemblage or some combination of parts that provide for physical circuit designs and various related structures. In various instances, a method of designing, providing and fabricating the power clamp architecture 104 as an integrated device may involve use of various circuit components and/or related structures described herein so as to thereby implement various power clamp techniques associated therewith. Also, the power clamp architecture 104 may be integrated with various circuitry and/or related components on a single chip, and also, the power clamp architecture 104 may be implemented in embedded devices for automotive, mobile, computer, server and IoT applications, including remote sensor nodes.

As shown in FIG. 1, power clamp architecture 104 may provide for distribution of electro-static discharge (ESD) that uses various power clamp schemes and techniques for various circuit related applications. Also, the power clamp architecture 104 may define a distribution structure having input-output circuitry 110 and power clamp circuitry 120 that are coupled to together so as to provide ESD protection. In some cases, the input-output circuitry 110 may be referred to as bi-directional input-output (BIDIR IO) circuitry. In some applications, the input-output circuitry 110 may include ESD assist circuitry 114 and driver circuitry 118, and also, the power clamp circuitry 120 may include resistor-capacitor (RC) trigger circuitry 124 and transistor circuitry 128, such as, e.g., big field-effect transistor (FET) circuitry, which may be referred to as big FET circuitry. Generally, the term “large” may be used to indicate length of a transistor device, and the term “big” may be used to indicate width of a transistor device, and thus, the width of the big field-effect transistor (i.e., big FET) may be in the order of thousands of microns in width.

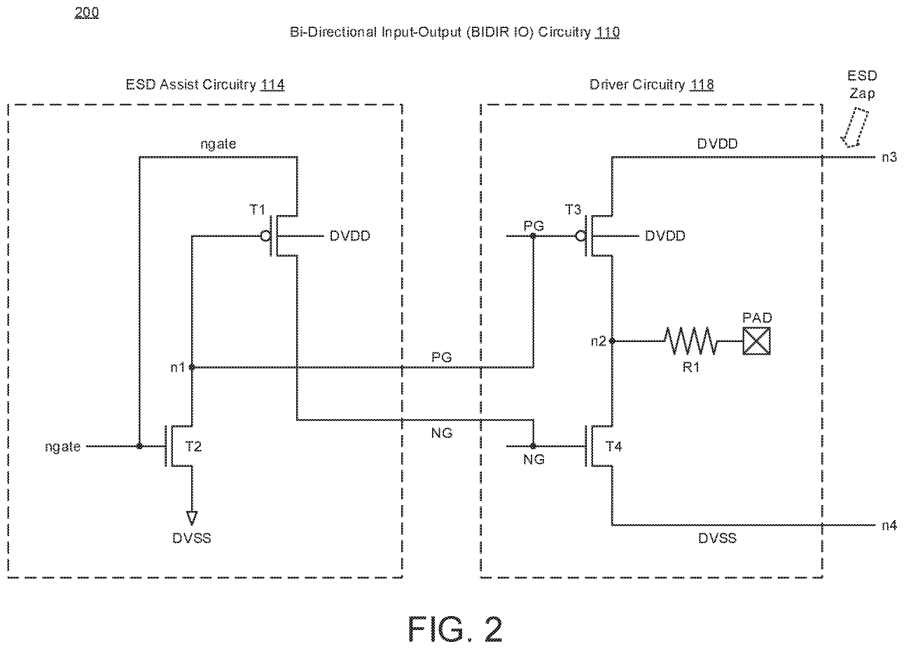

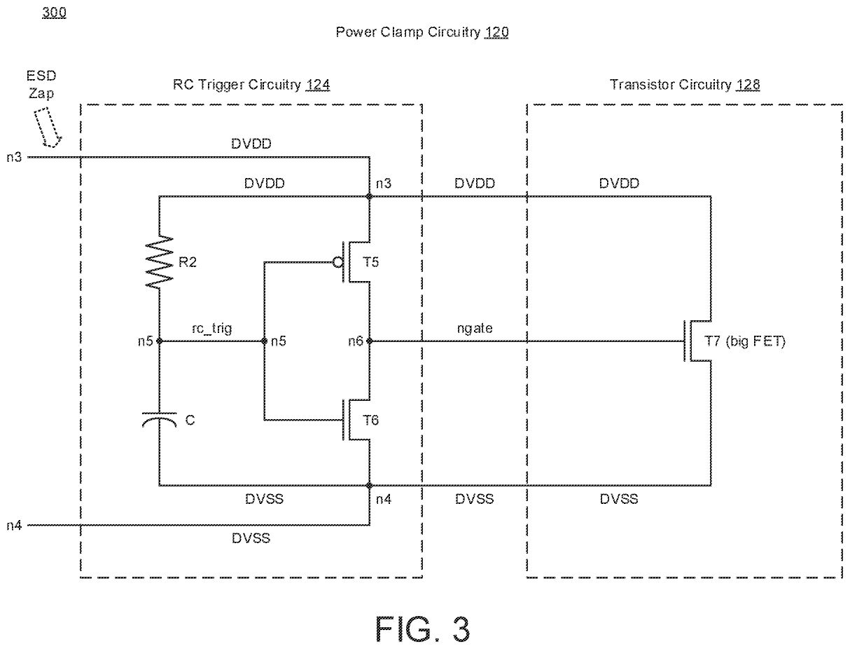

In some implementations, the input-output stage 110 may have first transistors (e.g., as shown in FIG. 2) coupled between a voltage supply (DVDD) and ground (DVSS or GND), and the power clamp stage 120 may have resistor-capacitor (RC) trigger circuitry 124 coupled in parallel with second transistors (e.g., as shown in FIG. 3) between the voltage supply (DVDD) and ground (DVSS or GND). Also, during a power surging event, electro-static discharge (ESD) may be distributed across the first and second transistors by way of passing from the voltage supply (DVDD) to ground (DVSS or GND). Additional features, characteristics and/or behaviors related to these circuitry 114, 118, 124, 128 are described in greater detail herein in reference to FIGS. 2-4.

FIG. 2 illustrates a diagram 200 of the input-output circuitry 110 in accordance with various implementations described herein.

In some implementations, the input-output circuitry 110 provides for fabricating electro-static discharge (ESD) related circuitry with various integrated circuit components arranged and/or coupled together as an assemblage or some combination of parts that provide for physical circuit designs and various related structures. In various instances, a method of designing, providing and/or fabricating the input-output circuitry 110 as an integrated device may involve use of various circuit components and/or related structures described herein so as to thereby implement various power clamp techniques associated therewith. Also, the input-output circuitry 110 may be integrated with various circuitry and/or related components on a single chip, and also, the input-output circuitry 110 may be implemented in embedded devices for automotive, mobile, computer, server and loT applications, including remote sensor nodes.

As shown in FIG. 2, the input-output circuitry 110 may be implemented as an input-output (IO) stage having the assist circuitry 114 and the driver circuitry 118 coupled between the voltage supply (DVDD) and ground (DVSS or GND). Also, the input-output (IO) stage or circuitry 110 may have first transistors (T1, T2, T3, T4) coupled between the voltage supply (DVDD) and ground (DVSS or GND). In some scenarios, during a sudden power surging event (ESD Zap), electro-static discharge (ESD) may be distributed across one or more of the first transistors (T1, T2, T3, T4) by way of passing from the voltage supply (DVDD) and ground (DVSS or GND). In some scenarios, during the sudden power surging event, electro-static discharge (ESD) may be distributed across the driver circuitry 118 when triggered by the ESD assist circuitry 114.

In some implementations, the first transistors (T1, T2, T3, T4) may have a first driving transistor (T3) and a second driving transistor (T4) coupled in series between the voltage supply (DVDD) and ground (DVSS or GND). Also, the input-output (IO) circuitry 110 may have an input-output pad (PAD) coupled to output node (n2) disposed between the first driving transistor (T3) and the second driving transistor (T4) by way of a resistor (R1). Also, the first transistors (T1, T2, T3, T4) may include a first assist transistor (T1) coupled between a gate of a second assist transistor (T2) and a gate of the second driving transistor (T4). Also, the first transistors (T1, T2, T3, T4) may include the second assist transistor (T2) coupled between a gate of the first assist transistor (T1) and ground (DVSS or GND), and also, the gate of the first assist transistor (T1) may be coupled to a gate of the first driving transistor (T3). Also, the voltage supply (DVDD) may be coupled to a bulk terminal (B) of the first driving transistor (T3), and also, the voltage supply (DVDD) may be coupled to a bulk terminal (B) of the first assist transistor (T1).

In some implementations, an ngate signal may be coupled to and applied to the gate of the second assist transistor (T2), and the ngate signal may also be coupled to and applied to an input of the first assist transistor (T1). Also, in some applications, the ngate signal coupled to the gate of transistor (T2) in FIG. 2 is the same as the ngate signal at node n6 coupled to the gate of transistor (T7) in FIG. 3. Also, a node signal taken from the n1 node may be referred to as a PG signal that is coupled to and applied to the gate of the first driving transistor (T3). Also, an output signal from the first assist transistor (T1) may be referred to as an NG signal that is coupled to and applied to the gate of the second driver transistor (T4) as the NG signal. Also, the voltage supply (DVDD) refers to a voltage supply rail that is coupled to a node (n3), and the ground (DVSS or GND) may refer to a ground supply rail that is coupled to a node (n4).

In various implementations, the first assist transistor (T1) may refer to a P-type transistor, such as, e.g., PFET, and also, the second assist transistor (T2) may refer to an N-type transistor, such as, e.g., NFET. Also, in various implementations, the first driving transistor (T3) may refer to a P-type transistor, such as, e.g., PFET, and also, the second driving transistor (T4) may refer to an N-type transistor, such as, e.g., NFET. However, in various other implementations, any different combination of P-type transistors (PFETs) and N-type transistors (NFETs) may be used in various different types of configurations so as to achieve similar scope, features, characteristics and/or behaviors.

FIG. 3 illustrates a diagram 300 of power clamp circuitry 120 in accordance with various implementations described herein.

In some implementations, the power clamp circuitry 120 provides for fabricating electro-static discharge (ESD) related circuitry with various integrated circuit components arranged and/or coupled together as an assemblage or some combination of parts that provide for physical circuit designs and various related structures. In various instances, a method of designing, providing and/or fabricating the power clamp circuitry 120 as an integrated device may involve use of various circuit components and/or related structures described herein so as to thereby implement various power clamp techniques associated therewith. Also, the power clamp circuitry 120 may be integrated with various circuitry and/or related components on a single chip, and also, the power clamp circuitry 120 may be implemented in embedded devices for automotive, mobile, computer, server and loT applications, including remote sensor nodes.

As shown in FIG. 3, the power clamp circuitry 120 may be implemented as a power clamping stage having the trigger circuitry 124 (e.g., as RC triggering circuitry) and transistor circuitry 128 (e.g., as big field-effect transistor FET circuitry) coupled between the voltage supply (DVDD) and ground (DVSS or GND). Also, the power clamping stage or circuitry 120 may have the trigger circuitry 124 (e.g., as resistor-capacitor RC triggering circuitry coupled in parallel with second transistors (T5, T6) between the voltage supply (DVDD) and ground DVSS or GND). In some scenarios, during a sudden power surging event (ESD Zap), electro-static discharge (ESD) may be distributed across one or more of the second transistors (T5, T6) by way of passing from the voltage supply (DVDD) and ground (DVSS or GND). Also, the power clamping stage or circuitry 124 may also include the big field-effect transistor (T7) (e.g., as a big FET) that is coupled between the voltage supply (DVDD) and ground (DVSS or GND). In some scenarios, during the sudden power surging event, the electro-static discharge (ESD) may be distributed across the big FET (T7) when triggered by the RC triggering circuitry 124.

In various implementations, the second transistors (T5, T6) may include a first triggering transistor (T5) and a second triggering transistor (T6) coupled in series between the voltage supply (DVDD) and ground (DVSS or GND). Also, the resistor-capacitor (RC) triggering circuitry 124 may include a resistor (R2) and a capacitor (C) coupled in series between the voltage supply (DVDD) and ground (DVSS or GND). Also, the resistor (R2) and the capacitor (C) of the resistor-capacitor (RC) triggering circuitry 124 may be coupled in parallel with the first triggering transistor (T5) and the second triggering transistor (T6), and also, a first triggering node (n5) disposed between the resistor (R2) and the capacitor (C) may be coupled to gates of the first triggering transistor (T5) and the second triggering transistor (T6). Also, in some instances, the second transistors (T5, T6) may include the big field-effect transistor (T7) (e.g., big FET) coupled in parallel with the first triggering transistor (T5) and the second triggering transistor (T6) between voltage supply (DVDD) and ground (DVSS or GND). Also, a second triggering node (n6) disposed between the first triggering transistor (T5) and the second triggering transistor (T6) may be coupled to a gate of the big field-effect transistor (T7).

In some implementations, an output signal from RC circuit (R2-C) may provide an RC triggering signal (rc_trig) at node (n5) that is coupled to and applied to the gates of the triggering transistors (T5, T6). Also, an ngate signal at node n6 may be taken from an output of the first triggering transistor (T5), and the ngate signal at node n6 may be coupled to and applied to the gate of the big FET (T7). Also, in some instances, the ngate signal at node n6 coupled to the gate of transistor (T7) in FIG. 3 is the same ngate signal coupled to the gate of transistor (T2) in FIG. 2. Also, the voltage supply (DVDD) refers to the voltage supply rail that is coupled to DVDD node (n3), and the ground (DVSS or GND) may refer to the ground supply rail that is coupled DVSS node (n4).

In various implementations, the first triggering transistor (T5) may refer to a P-type transistor, such as, e.g., PFET, and also, the second triggering transistor (T6) may refer to an N-type transistor, such as, e.g., NFET. Also, in various implementations, the big FET (T7) may refer to a N-type transistor, such as, e.g., NFET. However, in various other implementations, any different combination of P-type transistors (PFETs) and N-type transistors (NFETs) may be used in various different types of configurations so as to achieve similar scope, features, characteristics and/or behaviors.

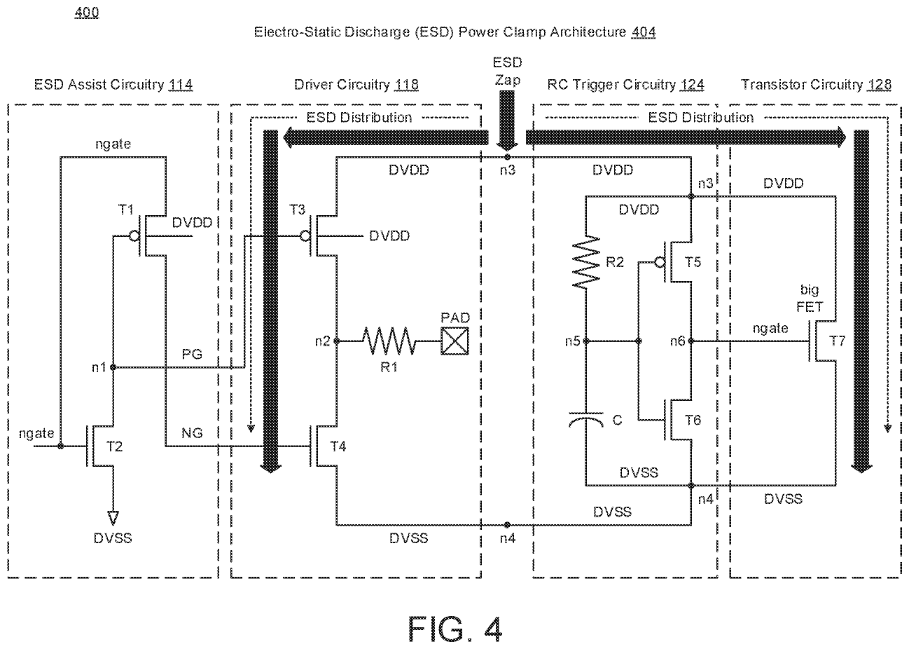

FIG. 4 illustrates a diagram 400 of distributing electro-static discharge (ESD) in power clamp architecture 404 in accordance with implementations described herein.

In some implementations, the power clamp architecture 404 is similar in scope to the power clamp architecture 104 in FIG. 1 and is also similar to a combination of the input-output circuitry 110 in FIG. 2 and the power clamp circuitry 120 in FIG. 3.

In some implementations, power clamp architecture 404 provides for fabricating electro-static discharge (ESD) related circuitry with various integrated circuit components arranged and/or coupled together as an assemblage or some combination of parts that provide for physical circuit designs and various related structures. In various instances, a method of designing, providing and fabricating the power clamp architecture 404 as an integrated device may involve use of various circuit components and/or related structures described herein so as to thereby implement various power clamp techniques associated therewith. Also, the power clamp architecture 404 may be integrated with various circuitry and/or related components on a single chip, and also, the power clamp architecture 404 may be implemented in embedded devices for automotive, mobile, computer, server and IoT applications, including remote sensor nodes.

As shown in FIG. 4, the power clamp architecture 404 may have input-output (IO) stage or circuitry (114, 118) with the ESD assist circuitry 114 and driver circuitry 118 coupled between the voltage supply (DVDD) and ground (DVSS or GND). Also, the power clamp architecture 404 may have power clamp stage or circuitry (124, 128) with triggering circuitry 124 (as RC trigger circuitry) and transistor circuitry 128 (as big FET circuitry) coupled between the voltage supply (DVDD) and ground (DVSS or GND).

In various implementations, during the sudden power surging event (ESD Zap), the electro-static discharge (ESD) may be distributed across the driver circuitry 118 when triggered by the ESD assist circuitry 114. Also, during the sudden power surging event (ESD Zap), the electro-static discharge (ESD) may also be distributed across the big field-effect transistor (T7) when triggered by the RC triggering circuitry 124. In some instances, big FET (T7) may refer to a big N-type transistor, such as, e.g., a big NFET. However, in other instances, a P-type transistor (big PFET) may be used in different configurations so as to achieve similar scope, features, characteristics and/or behaviors.

In various implementations, the driver circuitry 118 may include the first driving transistor (T3) and the second driving transistor (T4) that are coupled in series between the voltage supply (DVDD) and ground (DVSS or GND). Also, the input-output pad (PAD) may be coupled to the output node (n2) that is disposed between the first driving transistor (T3) and second driving transistor (T4) by way of the resistor (R1). Also, the ESD assist circuitry 114 may include the first assist transistor (T1) that is coupled between the gate of the second assist transistor (T2) and the gate of the second driving transistor (T4), and also, the second assist transistor (T2) may be coupled between the gate of the first assist transistor (T1) and ground (DVSS or GND), and also, the gate of the first assist transistor ((T1) may be coupled to the gate of the first driving transistor (T3) via node n1. Also, the voltage supply (DVDD) may be coupled to a bulk terminal (B) of the first driving transistor (T3) and to the bulk terminal (B) of the first assist transistor (T1).

In various implementations, the RC triggering circuitry 124 may include the first triggering transistor (T5) and second triggering transistor (T6) coupled in series between the voltage supply (DVDD) and ground (DVSS or GND). Also, the RC triggering circuitry 124 may include the resistor (R2) and capacitor (C) coupled in series between the voltage supply (DVDD) and ground (DVSS or GND). Also, the resistor (R2) and the capacitor (C) of RC triggering circuitry 124 may be coupled in parallel with the first triggering transistor (T5) and the second triggering transistor (T6), and also, first triggering node (n5) disposed between the resistor (R2) and the capacitor (c) may be coupled to the gates of the first triggering transistor (T5) and the second triggering transistor (T6). Also, big FET (T7) may be coupled in parallel with the first triggering transistor (T5) and the second triggering transistor (T6) of the RC triggering circuitry 124, and also, second triggering node (n6) disposed between the first triggering transistor (T5) and the second triggering transistor (T6) may be coupled to the gate of the big FET (T7).

In some implementations, as shown in FIG. 4, ESD current may be distributed between the power clamp circuitry (124, 128) and the driver circuitry 118. Also, in various implementations, with an increase in the number of BIDIRs (i.e., bi-directional IO circuits), only the RC triggering circuitry 124 may be needed, and as such, the Big FET (i.e., big FET in the power clamp circuitry 124, 128) may be optional.

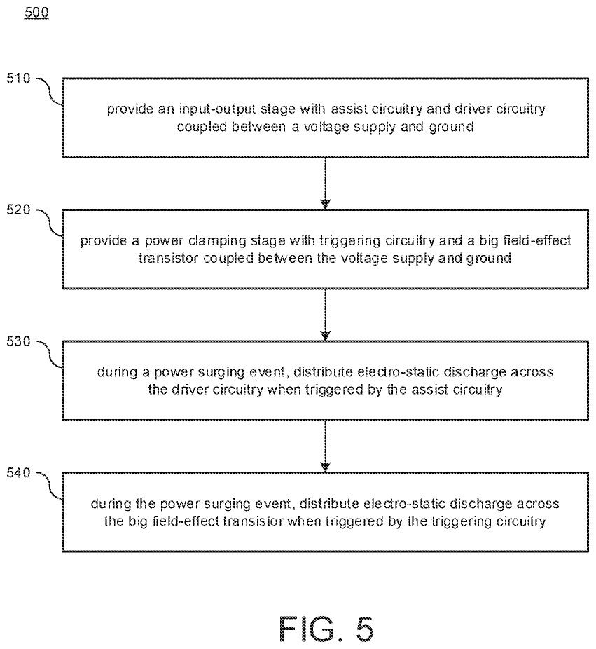

FIG. 5 illustrates a process flow diagram of a method 500 for providing power clamp architecture in accordance with implementations described herein.

It should be understood that even though the method 500 indicates a particular order of operation execution, in some instances, various certain portions of the operations may be executed in a different order, and on different systems. In other cases, additional operations and/or steps may be added to and/or omitted from method 500. Also, method 500 may be implemented in hardware and/or software. If implemented in hardware, the method 500 may be implemented with various components and/or circuitry, as described herein in FIGS. 1-4. Also, if implemented in software, method 500 may be implemented with program and/or software instruction processes configured for providing power clamp architecture, as described herein. Also, if implemented in software, instructions related to implementing the method 500 may be stored in memory and/or a database. In various instances, a computer or various other types of computing devices having a processor and memory may be configured to perform method 500.

In various implementations, method 500 may refer to a method for designing, providing, fabricating and/or manufacturing power clamp architecture for electro-static discharge (ESD) as an integrated system, device and/or circuit that involves use of various circuit components and related structures described herein so as to implement techniques associated therewith. Also, power clamp architecture may be integrated with computing circuitry and various related components on a single chip, and power clamp architecture may be implemented in various embedded systems for various electronic, mobile and loT applications, including remote sensor nodes.

At block 510, method 500 may provide an input-output stage with assist circuitry and driver circuitry coupled between a voltage supply and ground. At block 520, method 500 may provide a power clamping stage with triggering circuitry and a big field-effect transistor (FET) coupled between the voltage supply and ground. At block 530, during a power surging event, method 500 may distribute electro-static discharge across the driver circuitry when triggered by the assist circuitry. At block 540, during the power surging event, method 500 may distribute electro-static discharge across the big field-effect transistor (FET) when triggered by the triggering circuitry.

In various implementations, the driver circuitry may have a first driving transistor and a second driving transistor coupled in series between the voltage supply and ground, and an input-output pad may be coupled to an output node disposed between the first driving transistor and the second driving transistor by way of a resistor. Also, the assist circuitry may include a first assist transistor coupled between a gate of a second assist transistor and a gate of the second driving transistor, and the assist circuitry may include the second assist transistor coupled between the gate of the first assist transistor and ground, and also, the gate of the first assist transistor may be coupled to a gate of the first driving transistor. Also, in some instances, the voltage supply may be coupled to a bulk terminal of the first driving transistor and a bulk terminal of the first assist transistor.

In various implementations, the triggering circuitry may include a first triggering transistor and a second triggering transistor coupled in series between the voltage supply and ground, and the triggering circuitry may have a resistor and a capacitor coupled in series between the voltage supply and ground. Also, the resistor and the capacitor of the triggering circuitry may be coupled in parallel with the first triggering transistor and the second triggering transistor, and a first triggering node disposed between the resistor and capacitor may be coupled to gates of the first triggering transistor and second triggering transistor. Also, the big field-effect transistor (FET) may be coupled in parallel with the first triggering transistor and the second triggering transistor of the triggering circuitry, and a second triggering node disposed between the first triggering transistor and the second triggering transistor may be coupled to a gate of the big field-effect transistor.

It should be intended that the subject matter of the claims not be limited to the implementations and illustrations provided herein, but include modified forms of those implementations including portions of implementations and combinations of elements of different implementations in accordance with the claims. It should be appreciated that in the development of any such implementation, as in any engineering or design project, numerous implementation-specific decisions should be made to achieve developers' specific goals, such as compliance with system-related and business related constraints, which may vary from one implementation to another. Moreover, it should be appreciated that such a development effort may be complex and time consuming, but would nevertheless be a routine undertaking of design, fabrication, and manufacture for those of ordinary skill having benefit of this disclosure.

Described herein are various implementations of a device having an input-output stage with first transistors coupled between a voltage supply and ground. Also, the device may have a power clamping stage with resistor-capacitor circuitry coupled in parallel with second transistors between the voltage supply and ground. Also, during a power surging event, electro-static discharge is distributed across the first transistors and the second transistors by way of passing from the voltage supply to ground.

Described herein are various implementations of a device having an input-output stage with assist circuitry and driver circuitry coupled between a voltage supply and ground. Also, the device may have a power clamping stage having triggering circuitry and a big field-effect transistor coupled between the voltage supply and ground. In some instances, during a power surging event, electro-static discharge is distributed across the driver circuitry when triggered by the assist circuitry. Also, in some instances, during the power surging event, electro-static discharge is also distributed across the big field-effect transistor when triggered by the triggering circuitry.

Described herein are various implementations of a method. The method may provide an input-output stage with assist circuitry and driver circuitry coupled between a voltage supply and ground. Also, the method may provide a power clamping stage with triggering circuitry and a big field-effect transistor coupled between the voltage supply and ground. Also, during a power surging event, the method may distribute electro-static discharge across the driver circuitry when triggered by the assist circuitry. Also, during the power surging event, the method may distribute electro-static discharge across the big field-effect transistor when triggered by the triggering circuitry.

Reference has been made in detail to various implementations, examples of which are illustrated in the accompanying drawings and figures. In the following detailed description, numerous specific details are set forth to provide a thorough understanding of the disclosure provided herein. However, the disclosure provided herein may be practiced without these specific details. In some other instances, well-known methods, procedures, components, circuits and networks have not been described in detail so as not to unnecessarily obscure details of the embodiments.

It should also be understood that, although the terms first, second, etc. may be used herein to describe various elements, these elements should not be limited by these terms. These terms are only used to distinguish one element from another. For example, a first element could be termed a second element, and, similarly, a second element could be termed a first element. The first element and the second element are both elements, respectively, but they are not to be considered the same element.

The terminology used in the description of the disclosure provided herein is for the purpose of describing particular implementations and is not intended to limit the disclosure provided herein. As used in the description of the disclosure provided herein and appended claims, the singular forms “a,” “an,” and “the” are intended to include the plural forms as well, unless the context clearly indicates otherwise. The term “and/or” as used herein refers to and encompasses any and all possible combinations of one or more of the associated listed items. The terms “includes,” “including,” “comprises,” and/or “comprising,” when used in this specification, specify a presence of stated features, integers, steps, operations, elements, and/or components, but do not preclude the presence or addition of one or more other features, integers, steps, operations, elements, components and/or groups thereof.

As used herein, the term “if” may be construed to mean “when” or “upon” or “in response to determining” or “in response to detecting,” depending on the context. Similarly, the phrase “if it is determined” or “if [a stated condition or event] is detected” may be construed to mean “upon determining” or “in response to determining” or “upon detecting [the stated condition or event]” or “in response to detecting [the stated condition or event],” depending on the context. The terms “up” and “down”; “upper” and “lower”; “upwardly” and “downwardly”; “below” and “above”; and other similar terms indicating relative positions above or below a given point or element may be used in connection with some implementations of various technologies described herein.

While the foregoing is directed to implementations of various related techniques described herein, other and further implementations may be devised in accordance with the disclosure herein, which may be determined by the claims that follow.

Although the subject matter has been described herein in language specific to structural features and/or methodological acts, it should be understood that the subject matter defined in the appended claims is not necessarily limited to the specific features or acts described above. Rather, specific features and acts described above are disclosed as example forms of implementing the claims.

What is claimed is:

1. A device comprising:
an input-output stage having first transistors coupled between a voltage supply and ground; and
a power clamping stage having resistor-capacitor circuitry coupled in parallel with second transistors between the voltage supply and ground,
wherein during a power surging event, electro-static discharge is distributed across the first transistors and the second transistors by way of passing from the voltage supply to ground.

2. The device of claim 1, wherein:
the first transistors include a first driving transistor and a second driving transistor coupled in series between the voltage supply and ground, and
an input-output pad is coupled to an output node disposed between the first driving transistor and the second driving transistor by way of a resistor.

3. The device of claim 2, wherein:
the first transistors include a first assist transistor coupled between a gate of a second assist transistor and a gate of the second driving transistor,
the first transistors include the second assist transistor coupled between a gate of the first assist transistor and ground, and
the gate of the first assist transistor is coupled to a gate of the first driving transistor.

4. The device of claim 3, wherein:
the voltage supply is coupled to a bulk terminal of the first driving transistor, and
the voltage supply is coupled to a bulk terminal of the first assist transistor.

5. The device of claim 1, wherein:
the second transistors include a first triggering transistor and a second triggering transistor coupled in series between the voltage supply and ground, and
the resistor-capacitor circuitry includes a resistor and a capacitor coupled in series between the voltage supply and ground.

6. The device of claim 5, wherein:
the resistor and the capacitor of the resistor-capacitor circuitry are coupled in parallel with the first triggering transistor and the second triggering transistor, and
a first triggering node disposed between the resistor and the capacitor is coupled to gates of the first triggering transistor and the second triggering transistor.

7. The device of claim 5, wherein:
the second transistors include a big field-effect transistor coupled in parallel with the first triggering transistor and the second triggering transistor between the voltage supply and ground, and
a second triggering node disposed between the first triggering transistor and the second triggering transistor is coupled to a gate of the big field-effect transistor.

8. A device comprising:
an input-output stage having assist circuitry and driver circuitry coupled between a voltage supply and ground; and
a power clamping stage having triggering circuitry and a big field-effect transistor coupled between the voltage supply and ground,
wherein during a power surging event, electro-static discharge is distributed across the driver circuitry when triggered by the assist circuitry, and
wherein during the power surging event, electro-static discharge is also distributed across the big field-effect transistor when triggered by the triggering circuitry.

9. The device of claim 8, wherein:
the driver circuitry includes a first driving transistor and a second driving transistor coupled in series between the voltage supply and ground, and
an input-output pad is coupled to an output node disposed between the first driving transistor and the second driving transistor by way of a resistor.

10. The device of claim 9, wherein:
the assist circuitry includes a first assist transistor coupled between a gate of a second assist transistor and a gate of the second driving transistor,
the assist circuitry includes the second assist transistor coupled between a gate of the first assist transistor and ground, and
the gate of the first assist transistor is coupled to a gate of the first driving transistor.

11. The device of claim 10, wherein:
the voltage supply is coupled to a bulk terminal of the first driving transistor, and
the voltage supply is coupled to a bulk terminal of the first assist transistor.

12. The device of claim 8, wherein:
the triggering circuitry includes a first triggering transistor and a second triggering transistor coupled in series between the voltage supply and ground, and
the triggering circuitry has a resistor and a capacitor coupled in series between the voltage supply and ground.

13. The device of claim 12, wherein:
the resistor and the capacitor of the triggering circuitry are coupled in parallel with the first triggering transistor and the second triggering transistor, and
a first triggering node disposed between the resistor and the capacitor is coupled to gates of the first triggering transistor and the second triggering transistor.

14. The device of claim 12, wherein:
the big field-effect transistor is coupled in parallel with the first triggering transistor and the second triggering transistor of the triggering circuitry, and
a second triggering node disposed between the first triggering transistor and the second triggering transistor is coupled to a gate of the big field-effect transistor.

15. A method comprising:
providing an input-output stage with assist circuitry and driver circuitry coupled between a voltage supply and ground; and
providing a power clamping stage with triggering circuitry and a big field-effect transistor coupled between the voltage supply and ground,
during a power surging event, distributing electro-static discharge across the driver circuitry when triggered by the assist circuitry, and
during the power surging event, distributing electro-static discharge across the big field-effect transistor when triggered by the triggering circuitry.

16. The method of claim 15, wherein:
the driver circuitry includes a first driving transistor and a second driving transistor coupled in series between the voltage supply and ground, and
an input-output pad is coupled to an output node disposed between the first driving transistor and the second driving transistor by way of a resistor.

17. The method of claim 16, wherein:
the assist circuitry includes a first assist transistor coupled between a gate of a second assist transistor and a gate of the second driving transistor,
the assist circuitry includes the second assist transistor coupled between a gate of the first assist transistor and ground, and
the gate of the first assist transistor is coupled to a gate of the first driving transistor.

18. The method of claim 15, wherein:
the triggering circuitry includes a first triggering transistor and a second triggering transistor coupled in series between the voltage supply and ground, and
the triggering circuitry has a resistor and a capacitor coupled in series between the voltage supply and ground.

19. The method of claim 18, wherein:
the resistor and the capacitor of the triggering circuitry are coupled in parallel with the first triggering transistor and the second triggering transistor, and
a first triggering node disposed between the resistor and the capacitor is coupled to gates of the first triggering transistor and the second triggering transistor.

20. The method of claim 18, wherein:
the big field-effect transistor is coupled in parallel with the first triggering transistor and the second triggering transistor of the triggering circuitry, and
a second triggering node disposed between the first triggering transistor and the second triggering transistor is coupled to a gate of the big field-effect transistor.
